(19) United States
(12) Patent Application Publication
(10) Pub. No.: US 2013/0234005 A1
(43) Pub. Date: Sep. 12, 2013

(54) IMAGE SENSOR AND OPTICAL INTERACTION DEVICE USING THE SAME THEREOF

(71) Applicants: WINTEK (CHINA) TECHNOLOGY LTD., Dongguan City (CN); WINTEK CORPORATION, Taichung City (TW)

(72) Inventors: Wen-Chun Wang, Taichung City (TW); David E. Stevenson, Dexter, MI (US); Jyh-Yeuan Ma, Taoyuan City (TW); Chong-Yang Fang, Taichung City (TW); Tsung-Hsien Lin, Taichung City (TW); Tsung-Yen Hsieh, Taichung City (TW); Chia-Hung Yeh, Changhua County (TW)

(73) Assignees: WINTEK CORPORATION, Taichung City (TW); WINTEK (CHINA) TECHNOLOGY LTD., Dongguan City (CN)

(21) Appl. No.: 13/786,541

(22) Filed: Mar. 6, 2013

(30) Foreign Application Priority Data
Mar. 8, 2012 (TW) 101107969

(51) Int. Cl. H01L 27/146

(52) U.S. Cl. CPC H01L 27/14625
USPC 250/208.1

(57) ABSTRACT

An image sensor for detecting a first and a second image light in different directions is disclosed. The image sensing device comprises a polarization beam splitter, a liquid crystal switch, a polarizer, a lens module and an image sensing device. The polarization beam splitter receives and splits the first and the second image light respectively into a first penetrative light, a first reflective light, a second penetrative light and a second reflective light. The liquid crystal switch controls the phase delay of the first and the second reflective light. The polarizer is disposed on the light emitting side of the liquid switch to control the passage of the first or the second reflective light. The lens module focuses the first or the second reflective light at a focal point. The image sensing device is disposed at the focal point to sense the focused first or second reflective light.

This application claims the benefit of Taiwan application Serial No. 101107969, filed Mar. 8, 2012, the subject matter of which is incorporated herein by reference.

### BACKGROUND OF THE INVENTION

1. Field of the Invention

The invention relates in general to an image sensor, and more particularly to an image sensor capable of switching image sources in different directions and an optical interaction device using the same thereof.

2. Description of the Related Art

Along with the advance in technology, people's demand for everydayness recording, entertainment and security also increases, and various image sensors are provided in response to the market trends. The generally known image sensors such as camera, video recorder, vehicle recorder and monitor can shoot at a single and specific direction and is unable to shoot at more than two directions at the same time. When there is a need to shoot at two different directions, at least two sets of image sensors are needed or a rotation device is incorporated in the image sensor to rotate the lens.

However, two sets of image sensors not only incur more hardware cost and occupy extra space. Due to the restriction of space, sometimes the installation of an extra image sensor is infeasible. The image sensor incorporating a rotation device also needs to consider whether the installation position and space allows the image sensor to rotate at a large angle. Apart from the extra cost of rotation device, the image sensor incorporating a rotation device still has a problem of blind angles in shooting.

### SUMMARY OF THE INVENTION

The invention is directed to an image sensor capable of switching the image sources in different directions to selectively detect images in different directions. The optical interaction device having the said image sensor may selectively receive instructions denoted by the image lights in different directions, and has both two-dimensional and three-dimensional optical interaction functions.

According to an embodiment of the present invention, an image sensor for detecting a first and a second image light in different directions is disclosed. The image sensing device comprises a polarization beam splitter, a liquid crystal switch, a polarizer, a lens module and an image sensing device. The polarization beam splitter receives the first and the second image light, and then splits the first image light into a first penetrative light and a first reflective light and splits the second image light into a second penetrative light and a second reflective light. The liquid crystal switch controls the phase delay of the first penetrative light and the second reflective light. The polarizer is disposed on a light emitting side of the liquid switch to control the passage of the first or the second reflective light. The lens module focuses the first or the second reflective light at a focal point. The image sensing device is disposed at the focal point of the lens module to sense the focused first penetrative light or second reflective light.

According to another embodiment of the present invention, an image sensor for detecting a first and a second image light in different directions is disclosed. The image sensor comprises an optical splitter, a liquid crystal switch set, a lens module and an image sensing device. The optical splitter receives and transmits the first or the second image light to the first side of the optical splitter. The liquid crystal switch module comprises a first and a second liquid crystal switch. The first liquid crystal switch comprises a liquid crystal layer and a polarizer pair disposed on two opposite sides of the liquid crystal layer, and is disposed at a lateral side of the optical splitter closer to the first image light to control the passage of the first image light. The second liquid crystal switch comprises another liquid crystal layer and another polarizer pair disposed on two opposite sides of the another liquid crystal layer, and is disposed at another lateral side of the optical splitter closer to the second image light to control the passage of the second image light. The lens module focuses the first or the second image light at a focal point located on the first side of the optical splitter. The image sensing device is disposed at the focal point of the lens module to sense the focused first or second image light.

According to an alternate embodiment of the present invention, an optical interaction device capable of receiving the image sources in different directions is disclosed. The optical interaction device comprises a display panel and an image sensor disposed on the part of a lateral side of the display panel for detecting a first and a second image light in different directions. The image sensor comprises an optical splitter, a liquid crystal switch module, a lens module, an image sensing device and an image recognition system. The optical splitter receives and transmits a first or a second image light to the first side of the optical splitter. The liquid crystal switch module controls the passage of the first or the second image light. The lens module focuses the first or the second image light at a focal point located on the first side of the optical splitter. The image sensing device is disposed at the focal point of the lens module to sense the focused first or the focused second image light. The image recognition device recognizes an instruction denoted by the focused first image light or another instruction denoted by the focused second image light, wherein the focused first image light and the focused second image light are sensed by the image sensing device.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIGS. 1A˜1B are schematic diagrams of an image sensor according to a first embodiment of the invention;

FIGS. 2A˜2B are schematic diagrams of an image sensor according to a second embodiment of the invention;

FIGS. 3A˜3B are schematic diagrams of an image sensor according to a third embodiment of the invention;

FIGS. 4A˜4B are schematic diagrams of an image sensor according to a fourth embodiment of the invention;

FIGS. 5A˜5B are schematic diagrams of an optical interaction device according to an embodiment of the invention;

FIG. 6 is schematic diagrams of a monitoring system according to an embodiment of the invention.

### DETAILED DESCRIPTION OF THE INVENTION

### First Embodiment

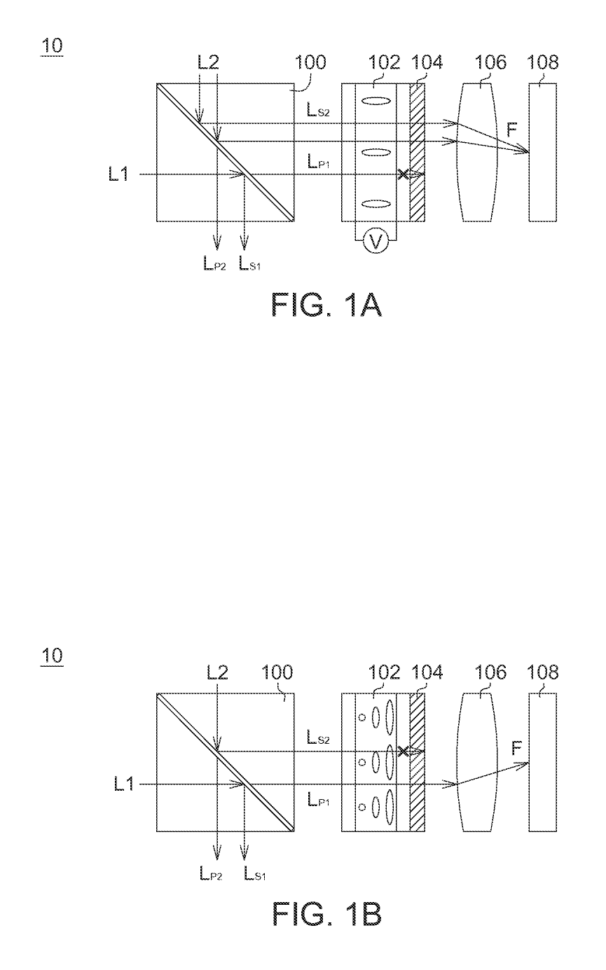

Referring to FIGS. 1A and 1B, schematic diagrams of an image sensor 10 according to a first embodiment of the invention are shown. As indicated in FIG. 1A, the image sensor 10 comprises a polarization beam splitter 100, a liquid crystal switch 102, a polarizer 104, a lens module 106 and an image sensing device 108. The polarizer 104 is disposed at the light emitting side of the liquid crystal switch 102. The lens module 106 is disposed between the liquid crystal switch 102 and the image sensing device 108. In the present embodiment, the polarization beam splitter 100 is realized by such as a polarization beam splitter (PBS), a dual brightness enhancement film dual brightness enhancement film (DBEF), or other reflective multi-layered films having the same function. The image sensing device 108 is realized by such as a complementary metal oxide semiconductor (CMOS) sensor.

In the present embodiment, the first image light L1 and the second image light L2 are substantially perpendicular to each other. The polarization beam splitter 100 receives the first image light L1 and the second image light L2, and further splits the first image light L1 into a first penetrative light L_{P1} and a first reflective light L_{S1} and splits the second image light L2 into a second penetrative light L_{P2} and a second reflective light L_{S2}. The statement that the first image light L1 and the second image light L2 are substantially perpendicular to each other implies that the angle between the first image light L1 and the second image light L2 does not need to be exactly equal to 90 degrees and other angles would also do as long as the incident angles of the first image light L1 and the second image light L2 fall within an angle range allowing the polarization beam splitter 100 to respectively split the first image light L1 and the second image light L2 into separate polarized lights having different phases.

It is noted that the polarization beam splitter 100 of FIGS. 1A and 1B is realized by a PBS type polarization beam splitter. However, the polarization beam splitter 100 may also be realized by a DBEF type polarization beam splitter as long as the DBEF type polarization beam splitter tilts at an angle to respectively split the first image light L1 and the second image light L2 into separate polarized lights having different phases. In the present embodiment, the PBS type polarization beam splitter 100 may function within about 7 degrees of the incident angle at which the incident light enters the PBS type polarization beam splitter 100; the DBEF type polarization beam splitter 100 may function within about 30 degrees of the incident angle at which the incident light enters the DBEF type polarization beam splitter 100.

As indicated in FIGS. 1A and 1B, only the optical paths of the first penetrative light L_{P1} and the second reflective light L_{S2} lead to the image sensing device 108. In the optical path, the liquid crystal switch 102 firstly controls the phase delay of the first penetrative light L_{P1} and the second reflective light L_{S2}, and then the polarizer 104 controls the passage of the first penetrative light L_{P1} or the second reflective light L_{S2}. The polarizer 104 is for example a polarizer only allows the s-polarized light to pass through. The lens module 106 focuses the first penetrative light L_{P1} passing through the polarizer 104 or the second reflective light L_{S2} passing through the polarizer 104 at a focal point F. The image sensing device 108 is disposed at the focal point F of the lens module 106 to sense the focused first penetrative light L_{P1} or second reflective light L_{S2}.

Firstly, referring to FIG. 1A, a schematic diagram of applying a voltage V to turn on the liquid crystal switch 102 according to a first embodiment is shown. As indicated in FIG. 1A, no image sensing devices is disposed in the proceeding direction of the first reflective light L_{S1} and the second penetrative light L_{P2}, and the first reflective light L_{S1} and the second penetrative light L_{P2} will not be detected. The first penetrative light L_{P1} and the second reflective light L_{S2} firstly pass through the enabled liquid crystal switch 102, which does not delay the phase of the light. For example, both the first penetrative light L_{P1} and the second penetrative light L_{P2} are such as a p-polarized light, and both the first reflective light L_{S1} and the second reflective light L_{S2} are such as an s-polarized light. The phase difference between the p-polarized light and the s-polarized light is ½λ. Meanwhile, the first penetrative light L_{P1} after passing through the enabled liquid crystal switch 102 is still a p-polarized light, and the second reflective light L_{S2} after passing through the enabled liquid crystal switch 102 is still an s-polarized light. Then, the first penetrative light L_{P1} and the second reflective light L_{S2} proceed to the polarizer 104 which only allows the s-polarized light to pass through. Eventually, only the second reflective light L_{S2} passes through the polarizer 104 and is further focused on the image sensing device 108 by the lens 106. That is, when the liquid crystal switch 102 of FIG. 1A is turned on, what is detected by the image sensing device 108 is the image of the second image light L2 in the incident direction.

Next, referring to FIG. 1B, a schematic diagram of not applying any voltages to the liquid crystal switch 102 so that the liquid crystal switch 102 is turned off according to a first embodiment is shown. Only the differences between and FIG. 1A and FIG. 1B are disclosed below, and the similarities are no repeated. As indicated in FIG. 1B, the first penetrative light L_{P1} and the second reflective light L_{S2} firstly pass through the disabled liquid crystal switch 102, which then delays the phase of the light. That is, the first penetrative light L_{P1} (p-polarized light) after passing through the disabled liquid crystal switch 102 will be delayed as an s-polarized light, and the second reflective light L_{S2} (s-polarized light) after passing through the disabled liquid crystal switch 102 will be delayed as a p-polarized light. When the delayed first penetrative light L_{P1} and the second reflective light L_{S2} proceed to the polarizer 104, which only allows the s-polarized light to pass through, only the delayed first penetrative light L_{P1} is able to pass through the polarizer 104 and is further focused on the image sensing device 108 by the lens 106. That is, when the liquid crystal switch 102 of FIG. 1B is turned off, what is detected by the image sensing device 108 is the image of the first image light L1 in the incident direction.

In the first embodiment, by turning on/off the liquid crystal switch 102, the image sensor 10 selectively detects the image of a first image light L1 or a second image light L2.

### Second Embodiment

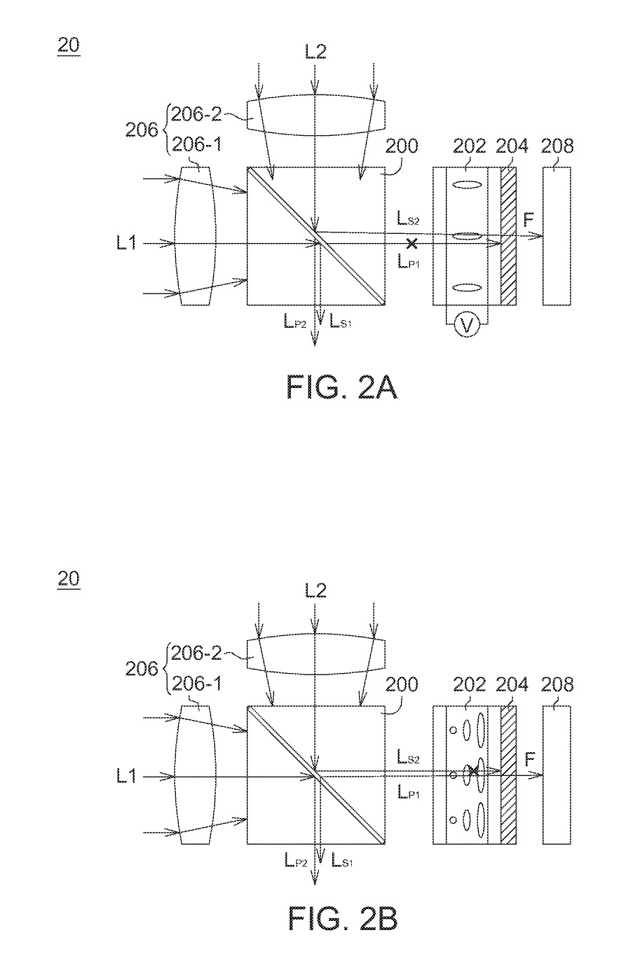

Referring to FIGS. 2A and 2B, schematic diagrams of an image sensor 20 according to a second embodiment of the invention are shown. As indicated in FIG. 2A, the image sensor 20 comprises a polarization beam splitter 200, a liquid crystal switch 202, a polarizer 204, a lens module 206, and an image sensing device 208. The polarizer 204 is disposed at the light emitting side of the liquid crystal switch 202. The polarization beam splitter 200, the liquid crystal switch 202, the polarizer 204 and the image sensing device 208 of the present embodiment are similar to corresponding elements of the first embodiment. Only the differences between the present embodiment and the first embodiment are disclosed, and other similarities are not repeated here.

As indicated in FIGS. 2A and 2B, the lens module 206 comprises a lens 206-1 and a lens 206-2. The first image light L1 firstly passes through a lens 206-1 and then proceeds to the polarization beam splitter 200. The second image light L2 firstly passes through a lens 206-2 and then proceeds to the polarization beam splitter 200. It is noted that, the lens 206-1 is disposed between the light source of the first image light L1 and the polarization beam splitter 200, and the lens 206-2 is disposed between the light source of the second image light L2 and the polarization beam splitter 200. The focal distances of the lens modules 206-1 and 206-2 are larger than the focal distance of the lens module 106 of the first embodiment, such that the first penetrative light L_{P1} or the second reflective light L_{S2} which passes through the lens module 206-1 and 206-2 may be focused at a focal point F. The image sensing device 208 is disposed at the focal point F of the lens module 206-1 and 206-2 to sense the focused first penetrative light L_{P1} or the focused second reflective light L_{S2}. The polarizer 204 controls the passage of the first penetrative light L_{P1} or the second reflective light L_{S2}.

Firstly, referring to FIG. 2A, a schematic diagram of applying a voltage V to turn on the liquid crystal switch 202 according to a second embodiment is shown. In the present embodiment, only the optical paths of the first penetrative light L_{P1} and the second reflective light L_{S2} lead to the image sensing device 208. The first penetrative light L_{P1} and the second reflective light L_{S2} firstly pass through the enabled liquid crystal switch 202, which does not delay the phase of the light. For example, both the first penetrative light L_{P1} and the second penetrative light L_{P2} are such as a p-polarized light, and both the first reflective light L_{S1} and the second reflective light L_{S2} are such as an s-polarized light. The first penetrative light L_{P1} after passing through the enabled liquid crystal switch 202 is still a p-polarized light, and the second reflective light L_{S2} after passing through the enabled liquid crystal switch 202 is still an s-polarized light. Then, the first penetrative light L_{P1} and the second reflective light L_{S2} proceed to the polarizer 204 which only allows the s-polarized light to pass through. Eventually, only the second reflective light L_{S2} is able to pass through the polarizer 204 and is further focused on the image sensing device 208. That is, when the liquid crystal switch 202 of FIG. 2A is turned on, what is detected by the image sensing device 208 is the image of the second image light L2 in the incident direction.

Next, referring to FIG. 2B, a schematic diagram of not applying any voltages to the liquid crystal switch 202 so that the liquid crystal switch 202 is turned off according to a second embodiment is shown. In the present embodiment, only the optical paths of the first penetrative light L_{P1} and the second reflective light L_{S2} lead to the image sensing device 208. The first penetrative light L_{P1} and the second reflective light L_{S2} firstly pass through the disabled liquid crystal switch 202. It is noted that after the first penetrative light L_{P1} and the second reflective light L_{S2} pass through the disabled liquid crystal switch 202, their phases will be delayed. For example, both the first penetrative light L_{P1} and the second penetrative light L_{P2} are such as a p-polarized light, and both the first reflective light L_{S1} and the second reflective light L_{S2} are such as an s-polarized light. The first penetrative light L_{P1} after passing through the disabled liquid crystal switch 202 will be delayed as an s-polarized light, and the second reflective light L_{S2} after passing through the disabled liquid crystal switch 202 will be delayed as a p-polarized light. Eventually, only the delayed first penetrative light L_{P1} is able to pass through the polarizer 204 (only the s-polarized light is allowed to pass through) to be focused on the image sensing device 208. That is, when the liquid crystal switch 202 of FIG. 2B is turned off, what is detected by the image sensing device 208 is the image of the first image light L1 in the incident direction.

### Third Embodiment

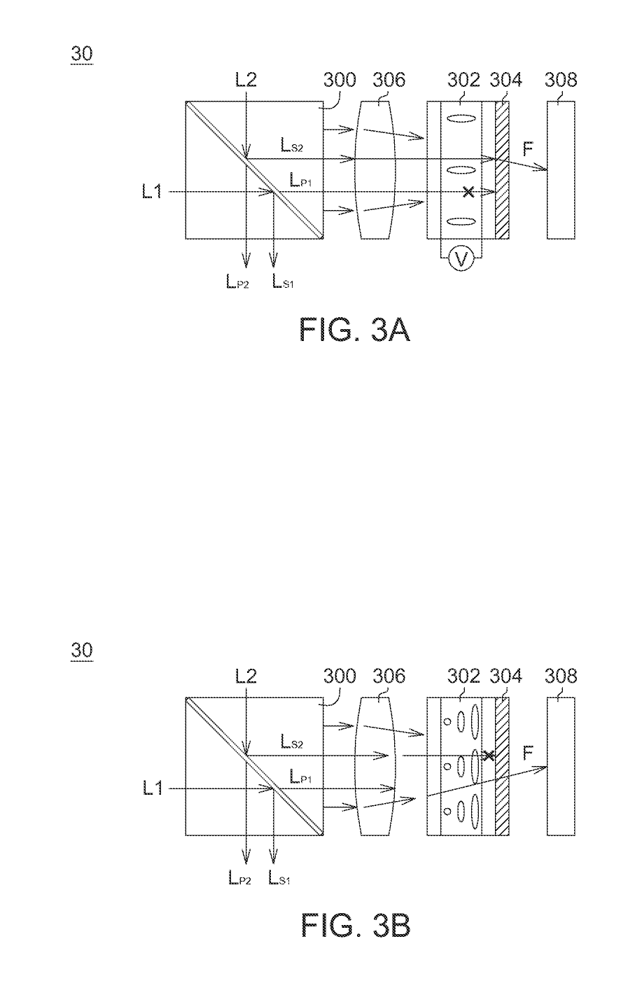

Referring to FIGS. 3A and 3B, schematic diagrams of an image sensor 30 according to a third embodiment of the invention are shown. As indicated in FIG. 3A, the image sensor 30 comprises a polarization beam splitter 300, a liquid crystal switch 302, a polarizer 304, a lens module 306 and an image sensing device 308. The polarization beam splitter 300, the liquid crystal switch 302, the polarizer 304 and the image sensing device 308 of the present embodiment are similar to corresponding elements of the second embodiment. Only the differences between the present embodiment and the first and the second embodiment are disclosed, and other similarities are not repeated here.

As indicated in FIGS. 3A and 3B, the lens module 306 is disposed between the polarization beam splitter 300 and the liquid crystal switch 302. The focal distance of the lens module 306 is between that of the lens module 106 of the first embodiment and that of the lens modules 206-1 and 206-2 of the second embodiment. The first penetrative light L_{P1} or the second reflective light L_{S2} which passes through the lens module 306 may be focused at a focal point F. The image sensing device 308 is disposed at the focal point F of the lens module 306 to sense the focused first penetrative light L_{P1} or the focused second reflective light L_{S2}. The polarizer 304 controls the passage of the first penetrative light L_{P1} or the second reflective light L_{S2}. The polarizer 304 of the present embodiment only allows the s-polarized light to pass through.

Firstly, referring to FIG. 3A, a schematic diagram of applying a voltage V to turn on the liquid crystal switch 302 according to a third embodiment is shown. After the first image light L1 and the second image light L2 proceed to the polarization beam splitter 300, the polarization beam splitter 300 splits the first image light L1 into a first penetrative light L_{P1} and a first reflective light L_{S1}, and splits the second image light L2 into a second penetrative light L_{P2} and a second reflective light L_{S2}. Both the first penetrative light L_{P1} and the second penetrative light L_{P2} are such as a p-polarized light, and both the first reflective light L_{S1} and the second reflective light L_{S2} are such as an s-polarized light. Only the optical paths of the first penetrative light L_{P1} and the second reflective light L_{S2} lead to the image sensing device 308. The first penetrative light L_{P1} and the second reflective light L_{S2} may be focused by the lens module 306. Before the first penetrative light L_{P1} and the second reflective light L_{S2} being focused at the focal point F, the first penetrative light L_{P1} and the second reflective light L_{S2} should be selected by the liquid crystal switch 302. Since the enabled liquid crystal switch 302 does not delay the phase of the light, the first penetrative light L_{P1} after passing through the enabled liquid crystal switch 302 is still a p-polarized light, and the second reflective light L_{S2} after passing through the enabled liquid crystal switch 302 is still an s-polarized light. Eventually, only the second reflective light L_{S2} is able to pass through the polarizer 304 (only the s-polarized light is allowed to pass through) to be focused at the focal point F. That is, when the liquid crystal switch 302 of FIG. 3A is turned on, what is detected by the image sensing device 308 is the image of the second image light L2 in the incident direction.

Next, referring to FIG. 3B, a schematic diagram of not applying any voltages to the liquid crystal switch 302 so that the liquid crystal switch 302 is turned off according to a third embodiment is shown. The similarities between FIG. 3A and FIG. 3B are not repeated here. It is noted that, after the first penetrative light L_{P1} and the second reflective light L_{S2} pass through the disabled liquid crystal switch 302, their phases will be delayed. That is, when the first penetrative light L_{P1} (p-polarized light) and the second reflective light L_{S2} (s-polarized light) proceed to the polarizer 304 which only allows the s-polarized light to pass through, only the delayed first penetrative light L_{P1} is able to pass through the polarizer 304 to be focused on the image sensing device 308. That is, when the liquid crystal switch 302 of FIG. 3B is turned off, what is detected by the image sensing device 308 is the image of the first image light L1 in the incident direction.

### Fourth Embodiment

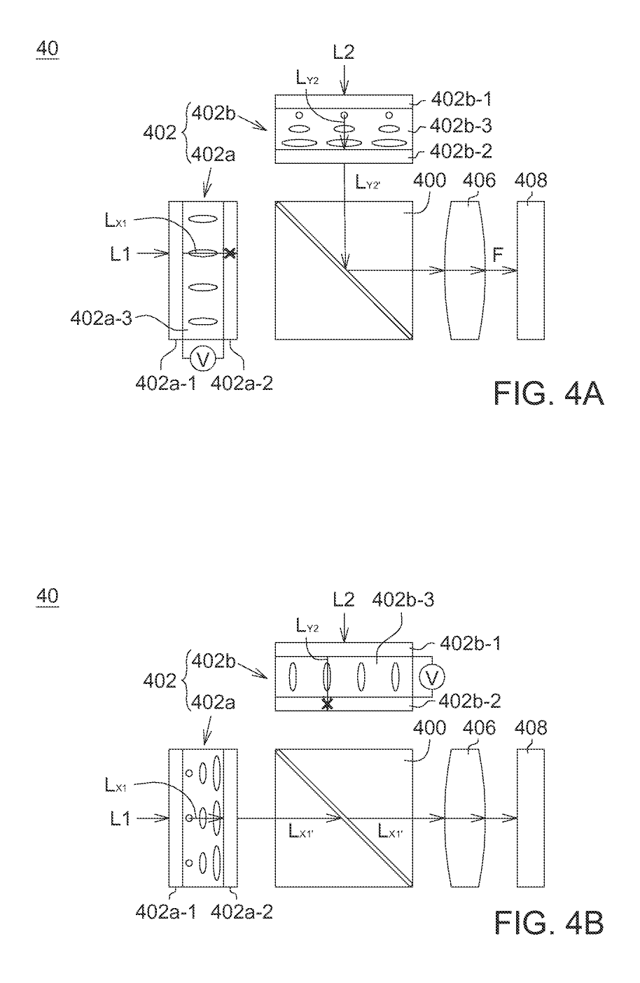

Referring to FIGS. 4A and 4B, schematic diagrams of an image sensor 40 according to a fourth embodiment of the invention are shown. The image sensor 40 may selectively detect a first image light L1 or a second image light L2, wherein the first image light L1 and the second image light L2 are substantially perpendicular to each other. As indicated in FIG. 4A, the image sensor 40 comprises an optical splitter 400, a liquid crystal switch module 402, a lens module 406 and an image sensing device 408. The lens module 406 and the image sensing device 408 of the present embodiment are similar to corresponding elements of the first embodiment. Only the differences between the present embodiment and the first embodiment are disclosed, and other similarities are not repeated here.

In the present embodiment, the optical splitter 400 may be realized by a beam splitter (BS) or a polarization beam splitter similar to the optical splitter 100 of the first embodiment. Details of the polarization beam splitter similar to the optical splitter 100 of the first embodiment are already disclosed above, and the similarities are not repeated here. The BS type beam splitter is a spectroscope which splits a light source into two unequal portions, one is penetrative and the other is reflective. The liquid crystal switch module 402 comprises a liquid crystal switch 402a and a liquid crystal switch 402b. The liquid crystal switch 402a is disposed outside the optical splitter 400 and closer to the first image light L1 to control the passage of the first image light L1. The liquid crystal switch 402b is disposed outside the optical splitter 400 and closer to the second image light L2 to control the passage of the second image light L2. The lens module 406 is disposed between the optical splitter 400 and the image sensing device 408 for focusing the first image light L1 passing through the optical splitter 400 or the second image light L2 passing through the optical splitter 400 at a focal point F. The image sensing device 408 is disposed at the focal point F of the lens module 406 to sense the focused first image light L1 or the focused second image light L2.

Firstly, referring to FIG. 4A, a schematic diagram of applying a voltage V to turn on the liquid crystal switch 402a and not applying any voltages to the liquid crystal switch 402b so that the liquid crystal switch 402b is turned off is shown. As indicated in FIG. 4A, the liquid crystal switch 402a comprises a liquid crystal layer 402a-3 and a pair of polarizers 402a-1 and 402a-2 disposed on two opposite sides of the liquid crystal layer 402a-3. The liquid crystal switch 402b comprises another liquid crystal layer 402b-3 and another pair of polarizers 402b-1 and 402b-2 disposed on two opposite sides of the liquid crystal layer 402b-3. Both the polarizer 402a-1 and the polarizer 402b-2 only allow the s-polarized light to pass through, and both the polarizer 402a-2 and the polarizer 402b-1 only allow the p-polarized light to pass through.

In the present embodiment, when the first image light L1 proceeds to the liquid crystal switch 402a, only the first s-polarized light L_{X1} may pass through the polarizer 402a-1 to enter the liquid crystal layer 402a-3. Since the enabled liquid crystal switch 402a does not delay the phase of the first s-polarized light L_{X1}, the first s-polarized light L_{X1} when proceeding to the polarizer 402a-2 cannot pass through the polarizer 402a-2. When the second image light L2 proceeds to the liquid crystal switch 402b, only the second p-polarized light L_{Y2} may pass through the polarizer 402b-1 to enter the liquid crystal layer 402b-3. The disabled liquid crystal switch 402b delays the phase of the second p-polarized light L_{Y2}, such that the second p-polarized light L_{Y2} is converted to a second s-polarized light L_{Y2′} which may pass through the polarizer 402b-2.

Continue to refer to FIG. 4A. The delayed second s-polarized light L_{Y2′} after passing through the polarizer 402b-2 is reflected to the lens module 406 by the optical splitter 400 and is further focused by the lens module 406 to form an image on the image sensing device 408. That is, in FIG. 4A, when the liquid crystal switch 402a is turned on and the liquid crystal switch 402b is turned off, what is detected by the image sensing device 408 is the image of the second image light L2 in the incident direction.

Referring to FIG. 4B, a schematic diagram of applying a voltage V to turn on the liquid crystal switch 402b and not applying any voltages to the liquid crystal switch 402a so that the liquid crystal switch 402a is turned off is shown. Only the differences between FIG. 4A and FIG. 4B are disclosed, and the similarities are no repeated.

It is noted that, when the first image light L1 proceeds to the liquid crystal switch 402a, only the first s-polarized light L_{X1} may pass through the polarizer 402a-1 to enter the liquid crystal layer 402a-3. The disabled liquid crystal switch 402a delays the phase of the first s-polarized light L_{X1}, such that the first s-polarized light L_{X1} is converted into a first p-polarized light L_{X1′}, which may pass through the polarizer 402a-2. When the second image light L2 proceeds to the liquid crystal switch 402b, only the second p-polarized light L_{Y2} may pass through the polarizer 402b-1 to enter the liquid crystal layer 402b-3. Since the enabled liquid crystal switch 402b does not delay the phase of the second p-polarized light L_{Y2}, the second p-polarized light L_{Y2} cannot pass through the polarizer 402b-2.

Continue to refer to FIG. 4B. The delayed first p-polarized light L_{X1′} after passing through the polarizer 402a-2 may penetrate the optical splitter 400 to reach the lens module 406, and is further focused by the lens module 406 to form an image on the image sensing device 408. That is, in FIG. 4B, when the liquid crystal switch 402a is turned off and the liquid crystal switch 402b is turned on, what is detected by the image sensing device 408 is the image of the first image light L1 in the incident direction.

It is noted that an embodiment in which the lens module 406 is disposed between the optical splitter 400 and the image sensing device 408 is used for description purpose. However, the lens module 406 may comprise two lenses (not illustrated) respectively disposed between the optical splitter 400 and the liquid crystal switch 402a and between the optical splitter 400 and the liquid crystal switch 402b. Alternatively, the two lenses may also be respectively disposed outside the liquid crystal switch 402a and closer to the first image light L1 source, and outside the liquid crystal switch 402b and closer to the second image light L2 source. Other arrangements of the lens module may also do as long as the lens module 406 is disposed in the optical path leading the first image light L1 and the second image light L2 to the front of the image sensing device 408 and the image sensing device 408 located at the focal point of the lens module 406. In the present embodiment, by turning on/off the liquid crystal switch 402a and the liquid crystal switch 402b, the first image light L1 and the second image light L2 are selectively transmitted to the image sensing device 408 to form an image.

### Application of the Image Sensor Disclosed in Above Embodiments:

The above embodiments may be used in different types of optical interaction device or image monitoring systems, and a number of applications are disclosed below for exemplification purpose.

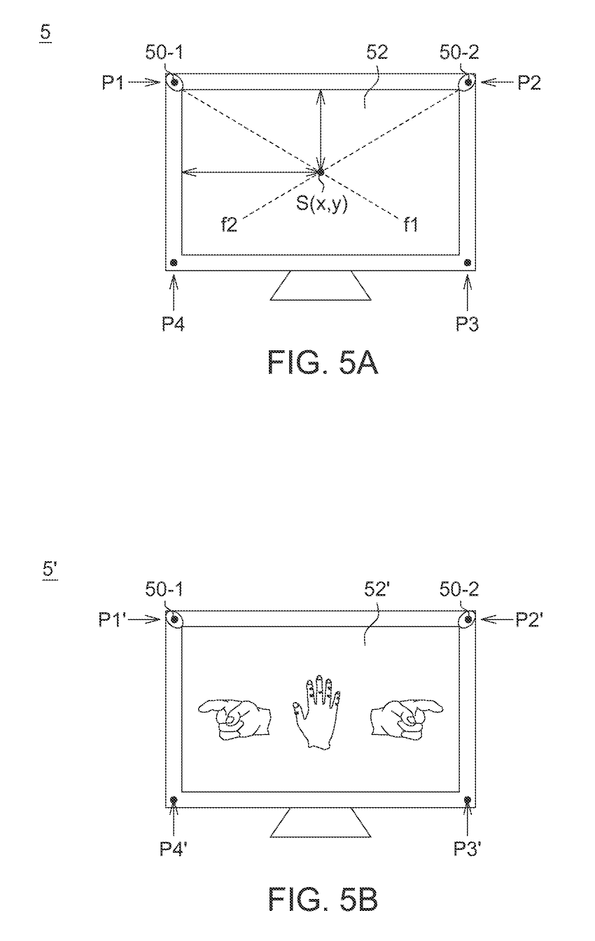

Referring to FIG. 5A, a schematic diagram of an optical interaction device 5 according to an embodiment of the invention is shown. The optical interaction device 5 comprises an image sensor 50-1, an image sensor 50-2, and a display panel 52. The image sensor 50-1 and the image sensor 50-2 may be realized by any types of image sensors 1040 of the first to the fourth embodiment. As indicated in FIG. 5A, the image sensor 50-1 and the image sensor 50-2 are disposed at different positions on a lateral side of the display panel 52. Preferably, the image sensor 50-1 and the image sensor 50-2 respectively are disposed at any two non-diagonal positions of the apex angles P1-P4 of the display panel 52. When the display panel 52 receives a touch signal S, the image sensor 50-1 may position the touch signal S as being located on a dummy line f1, and the image sensor 50-2 may position the touch signal S as being located on a dummy line f2. Thus, through the use of two image sensors, the touch signal S is positioned as being at the intersection between the dummy line f1 and the dummy line f2, and the two-dimensional positioning function of the touch panel can thus achieved. In the present embodiment, the touch signal S does not have to contact the display panel 52 as long as the touch signal S may be detected by the image sensor 50-1 and the image sensor 50-2.

Referring to FIG. 5B, a schematic diagram of an optical interaction device 5′ according to an embodiment of the invention is shown. The optical interaction device 5′ comprises an image sensor 50-1, an image sensor 50-2, the display panel 52′ and an image recognition device (not illustrated). The image sensor 50-1, the image sensor 50-2 and the display panel 52′ are similar to corresponding elements of FIG. 5A, and the similarities are not repeated here. In the present embodiment, when the user sends an instruction (such as a hand gesture or a body movement) in front of the display panel 52′, the image sensor 50-1 and the image sensor 50-2 may obtain the user's instruction and further transfer the instruction to the image recognition system, which recognizes the instruction denoted by the light signal sensed by the image sensor 50-1 and the image sensor 50-2. Therefore, the three-dimensional instruction sent by the user in front of the display panel 52′ can thus be recognized by the image sensor 50-1 and the image sensor 50-2.

In the present embodiment, two image sensors are exemplified for description purpose. However, one image sensor alone may also achieve two-dimensional positioning and three-dimensional instruction recognition for the optical interaction device 5′.

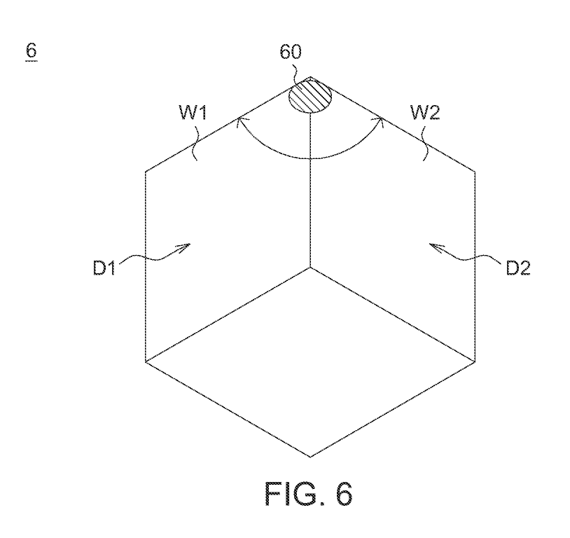

Referring to FIG. 6, a schematic diagram of a monitoring system 6 according to an embodiment of the invention is shown. In the present embodiment, the monitoring system 6 comprises an image sensor 60 and a memory element (not illustrated). The image sensor 60 may be realized by any types of image sensors 1040 of the first to the fourth embodiment. As indicated in FIG. 6, the wall W1 and the wall W2 are substantially perpendicular to each other. The image sensor 60 is disposed at a corner between the wall W1 and the wall W2 to monitor a range crossing direction D1 (the image of the incident light source substantially parallel to the wall W1) and direction D2 (the image of the incident light source substantially parallel to the wall W2). In other words, the monitoring system 6 equipped with an image sensor 60 may quickly switch between the image in the direction D1 and the image in the direction D2 to instantly monitor the images in the directions D1 and D2.

To summarize, the image sensor disclosed in the above embodiments of the invention switch to the image light source in different directions to selectively detect the image light source in different directions. Thus, the optical interaction device using the image sensor provides both the two-dimensional positioning function and the three-dimensional instruction recognition function. Besides, the monitoring system using the image sensor of the above embodiments of the invention may quickly switch and detect the image in different directions, resolves the blind angle problem encountered in conventional monitoring system image, reduces the hardware cost occurring when multiple monitors or rotation devices are required, and is less restricted by the space of installation.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An image sensor for detecting a first image light and a second image light in different directions, wherein the image sensor comprises:
a polarization beam splitter receiving the first image light and the second image light and then splitting the first image light into a first penetrative light and a first reflective light and splitting the second image light into a second penetrative light and a second reflective light;
a liquid crystal switch controlling the phase delay of the first penetrative light and the second reflective light;
a polarizer disposed on a light emitting side of the liquid switch for controlling the passage of the first penetrative light or the second reflective light;
a lens module focusing the first penetrative light or the second reflective light at a focal point; and
an image sensing device disposed at the focal point of the lens module to sense the focused first penetrative light or the focused second reflective light.

2. The image sensor according to claim 1, wherein the lens module comprises a first lens and a second lens, the first lens is disposed at a lateral side of the polarization beam splitter closer to the first image light, and the second lens is disposed at another lateral side of the polarization beam splitter closer to the second image light.

3. The image sensor according to claim 1, wherein the lens module is a lens disposed between the polarization beam splitter and the liquid crystal switch or between the image sensing device and the liquid crystal switch.

4. The image sensor according to claim 1, wherein the polarization beam splitter is a polarization beam splitter (PBS) or a dual brightness enhancement film (DBEF).

5. An image sensor for detecting a first image light and a second image light in different directions, the image sensor comprises:
an optical splitter receiving and transmitting the first or the second image light to a first side of the optical splitter;
a liquid crystal switch module, comprising:
a first liquid crystal switch, comprising a liquid crystal layer and a polarizer pair disposed on two opposite sides of the liquid crystal layer, and disposed at a lateral side of the optical splitter closer to the first image light to control the passage of the first image light; and
a second liquid crystal switch, comprising another liquid crystal layer and another polarizer pair disposed on two opposite sides of the another liquid crystal layer, and disposed at another lateral side of the optical splitter closer to the second image light to control the passage of the second image light;
a lens module focusing the first image light or the second image light at a focal point located on the first side of the optical splitter; and
an image sensing device disposed at the focal point of the lens module to sense the focused first image light or second image light.

6. The image sensor according to claim 5, wherein the lens module comprises a first lens and a second lens, the first lens is disposed at the lateral side of the optical splitter closer to the first image light, and the second lens is disposed at the another lateral side of the optical splitter closer to the second image light.

7. The image sensor according to claim 5, wherein the lens module is a lens disposed between the optical splitter and the image sensing device.

8. The image sensor according to claim 5, wherein the optical splitter is a polarized beam splitter (PBS) or a dual brightness enhancement film (DBEF).

9. An optical interaction device receiving image sources in different directions, wherein the optical interaction device comprises:
a display panel;
an image sensor disposed on a first position of the display panel for detecting a first image light and a second image light in different directions, wherein the first position is located on a lateral side of the display panel, and the image sensor comprises:
an optical splitter receiving and transmitting the first image light or the second image light to a first side of the optical splitter;
a liquid crystal switch module controlling the passage of the first image light or the second image light;
a lens module focusing the first image light or the second image light at a focal point located on the first side of the optical splitter;
an image sensing device disposed at the focal point of the lens module to sense the focused first image light or the focused second image light; and
an image recognition system recognizing an instruction denoted by the focused first image light or another instruction denoted by the focused second image light, wherein the focused first image light and the focused second image light are sensed by the image sensing device.

10. The optical interaction device according to claim 9, further comprising another image sensor disposed on a second position located on another lateral side of the display panel.
